(19) United States
(12) Patent Application Publication
(10) Pub. No.: US 2003/0161193 A1
(43) Pub. Date: Aug. 28, 2003

(54) Data storage and exchange device

(75) Inventors: Dov Moran, Kfar Saba (IL); Menahem Lasser, Kohav-Yair (IL)

Correspondence Address: DR. MARK FRIEDMAN LTD., c/o Bill Polkinghorn, Discovery Dispatch, 9003 Florin Way, Upper Marlboro, MD, 20772, US

(73) Assignee: M-SYSTEMS FLASH DISK PIONEERS LTD.

(21) Appl. No.: 10/133,464

(22) Filed: Apr. 29, 2002

Related U.S. Application Data
(63) Continuation-in-part of application No. 10/084,226, filed on Feb. 28, 2002.
(60) Provisional application No. 60/365,621, filed on Mar. 20, 2002.

(51) Int. Cl. G11C 7/00

(52) U.S. Cl. 365/200

(57) ABSTRACT

A data storage and exchange device includes a non-volatile memory, a first interface for exchanging data between the non-volatile memory and a computer, and a second interface for exchanging data between the non-volatile memory and a mass storage device. The data storage and exchange device is operative only to exchange data between the non-volatile memory and the computer, between the computer and the mass storage device, and possibly between the non-volatile memory and the mass storage device even in the absence of the computer.

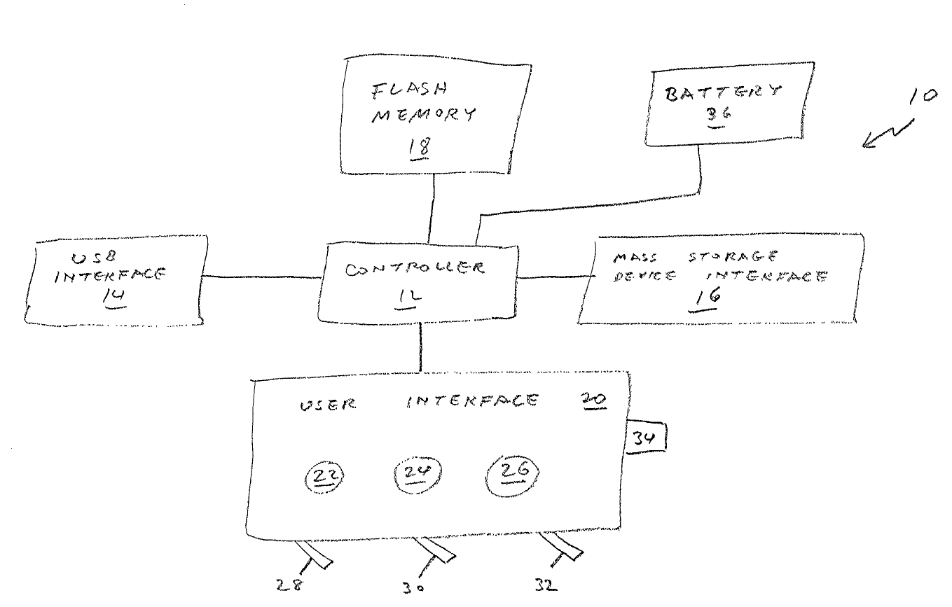

This is a continuation-in-part of U.S. Provisional Patent Application Ser. No. 60/365,621, filed Mar. 20, 2002. This is also a continuation-in-part of U.S. patent application Ser. No. 10/084,226, filed Feb. 28, 2002.

### FIELD AND BACKGROUND OF THE INVENTION

The present invention relates to data storage devices and, more particularly, to a data storage device that is operative to exchange data, both with a computer and with another data storage device.

Easily portable mass storage devices, that serve as detachable data storage media for computers, are known. One such device is described in U.S. Pat. No. 6,148,354, and is manufactured and sold by M-Systems Flash Disk Pioneers Ltd. of Tel Aviv, Israel as the DiskOnKey™. This device is operative, when plugged into a Universal Serial Bus (USB) port of a computer with an appropriately configured operating system, to emulate a hard disk. For example, an appropriately configured Windows operating system of a personal computer with a USB port could treat the computer's internal hard disk as the “C” drive and a DiskOnKey™ plugged into the USB port as the “E” drive. Other such mass storage devices include the family of Microdrives™, available from International Business Machines of Armonk N.Y., USA; and the CompactFlash™, the Memory Stick®, the Secure Digital Card™, the MultiMedia Card™ and the SmartMedia Card™, all available from SanDisk Corporation of Sunnyvale Calif., USA.

A typical mass storage device includes a non-volatile memory for long-term storage of data, an interface such as a USB interface for exchanging the data with a host computer, and a controller for managing the non-volatile memory. Controller activities include keeping track of free and occupied areas of the non-volatile memory; formatting data received from the host computer for storage in a designated area of the non-volatile memory and then writing the suitably formatted data to the designated area; and reading data from a designated area of the non-volatile memory and formatting the read data for transmission to the host computer. Typically, the data processing operations that are performed by mass storage devices are confined to reformatting, compression, decompression, encryption and decryption of the data.

U.S. patent application Ser. No. 10/084,226, which is incorporated by reference for all purposes as if fully set forth herein, teaches a mass storage device that is operative to exchange data, either with a computer or with another similar mass storage device. In other words, two such mass storage devices can exchange data directly without the intervention of a computer.

### SUMMARY OF THE INVENTION

According to the present invention there is provided a data storage and exchange device including: (a) a non-volatile memory; (b) a first interface, for exchanging data between a computer and the non-volatile memory; and (c) a second interface, for exchanging data between the computer and a mass storage device; the data storage and exchange device being operative only to perform the exchanging.

According to the present invention there is provided a data storage and exchange device including: (a) a non-volatile memory; (b) a first interface, for exchanging data between a computer and the non-volatile memory; and (c) a second interface, for exchanging data between the computer and a mass storage device, and for exchanging data between the non-volatile memory and the mass storage device; the data storage and exchange device being operative only to perform the exchanging.

In the present context, “exchanging” data between two devices includes reading data from one device and writing the data to another device. This “exchanging” may include limited processing of the data, as in prior art mass storage devices, that is needed for storing and retrieving the data.

In its most basic form, the present invention is a mass storage device that, like the prior art mass storage devices discussed above, includes a non-volatile memory and a first interface for exchanging data between the non-volatile memory and a host computer, but also includes a second interface for exchanging data between the host computer and a second mass storage device. So, for example, the basic device of the present invention can be used, in conjunction with a prior art mass storage device plugged into the second interface, to emulate two hard disks. A more advanced embodiment of the present invention is operative also to exchange data directly between the non-volatile memory and the second mass storage device via the second interface, without reference to the host computer and even in the absence of the host computer.

An important limitation of the present invention, that distinguishes the present invention from “computers” as herein defined, is that the operations of the present invention are confined to exchanges of data between the host computer and the non-volatile memory, between the host computer and a second mass storage device, and, in the advanced embodiment of the present invention, between the non-volatile memory and the second mass storage device. In particular, the data processing performed by the present invention is restricted to operations, such as reformatting, compression, decompression, encryption and decryption, that are directly related to these data exchanges.

Preferably, the non-volatile memory is a flash memory.

In one embodiment of the present invention, the first interface is a direct contact interface: the device of the present invention is in direct physical contact with the host computer. Examples of such interfaces include USB interfaces and interfaces such as the FireWire™ interface used by Apple Computer, Inc. of Cupertino Calif., USA in its product line, that conform with the IEEE 1394 standard. In another embodiment of the present invention, the first interface is a wireless interface such as a Bluetooth interface.

Preferably, the device of the present invention includes a controller for managing the exchange of data between the host computer and the non-volatile memory via the first interface, between the host computer and another mass storage device via the second interface, and, in the advanced embodiment of the present invention, between the non-volatile memory and the other mass storage device via the second interface If the two interfaces are dissimilar, the controller is operative to reformat input from one interface to be compatible with the other interface.

When the advanced embodiment of the present invention writes data from the non-volatile memory to a second mass storage device, the data that is written to the second mass storage device may be appended to other data previously stored in the second mass storage device, or may be written over other data previously stored in the second mass storage device. The data that is written to the second mass storage device may be structured as a single file, or may be structured with the same file structure as is used in the non-volatile memory. Conversely, when the advanced embodiment of the present invention reads data from a second mass storage device and writes that data to the non-volatile memory, that data may be appended to other data previously stored in the non-volatile memory, or may be written over other data previously stored in the non-volatile memory. The data that is written to the non-volatile memory may be structured as a single file, or may be structured with the same file structure as is used in the second mass storage device.

Exchanges of data between a host computer and the non-volatile memory via the first interface, or between a host computer and a second mass storage device via both interfaces, are initiated by the host computer. Preferably, to enable operation independent of a host computer, the advanced embodiment of the present invention includes a user interface for indicating which exchange mode (read from the second mass storage device vs. write to the second mass storage device; append vs. overwrite; single file structure vs. same file structure) to implement between the non-volatile memory and the second mass storage device.

### BRIEF DESCRIPTION OF THE DRAWINGS

The invention is herein described, by way of example only, with reference to the accompanying drawings, wherein:

The sole FIGURE is a block diagram of the present invention.

### DESCRIPTION OF THE PREFERRED EMBODIMENTS

The present invention is of a data storage and exchange device which can be used both for data storage and for independent exchanges of data with a computer and with a mass storage device.

The principles and operation of a data storage and exchange device according to the present invention may be better understood with reference to the drawings and the accompanying description.

Referring now to the drawings, the sole FIGURE is a block diagram of a typical data storage and exchange device 10 of the present invention. Like the prior art mass storage devices discussed above, device 10 includes a non-volatile memory 18 (specifically, a flash memory), a first interface 14 (specifically, a USB interface) to a computer, and a controller 12. As in the case of the prior art DiskOnKey™, when USB interface 14 is plugged into the USB port of a computer with an appropriately configured operating system, device 10 functions as an auxiliary hard disk of the computer. The computer writes data to flash memory 18 and reads data from flash memory 18, via USB interface 14 and controller 12. Controller 12 manages flash memory 18 much as the controller of a DiskOnKey™ manages the flash memory of that device.

Device 10 also includes a second interface 16 to a prior art mass storage device such as the Memory Stick®. When a Memory Stick® is inserted in interface 16 and USB interface 14 is plugged into the USB port of a computer with an appropriately configured operating system, device 10 allows the computer to use the Memory Stick® as a second auxiliary hard disk. For example, an appropriately configured Windows operating system of a personal computer with a USB port could treat the computer's internal hard disk as the “C” drive, flash memory 18 as the “E” drive and the Memory Stick® as the “F” drive. Read, write and erase commands from the computer to the second auxiliary hard disk are passed from USB interface 14 to the Memory Stick® via second interface 16. Note that when device 10 is plugged into a computer to emulate one or two auxiliary hard disks, all read, write and erase activities that involve device 10 are initiated by the computer.

In general, if both interfaces 14 and 16 are of the same type, for example if both interfaces 14 and 16 are USB interfaces, then the read, write and erase commands from the computer to the second auxiliary hard disk are passed directly from interface 14 to the prior art mass storage device via interface 16. If interfaces 14 and 16 are not of the same type, controller 12 reformats the commands received via interface 14 to be compatible with interface 16, and reformats data exchanged via interface 16 to be compatible with interface 14.

When device 10 is plugged into a computer equipped with a display device such as a video screen, a user can view the data stored in flash memory 18. If, in addition, a mass storage device such as a Memory Stick® is inserted in second interface 16, the user also can view data stored in the mass storage device.

When device 10 is not plugged into a computer, but a mass storage device such as a Memory Stick® is inserted in interface 16, device 10 is operative to exchange data between the Memory Stick® and flash memory 18, under the control of a user. For this purpose, a user interface 20 is provided. User interface 20 includes three LEDs 22, 24 and 26, three toggle switches 28, 30 and 32, and a button 34.

Toggle switch 28 is used to toggle between two different data exchange directions: either from flash memory 18 as a data source to the mass storage device as a data target or from the mass storage device as a data source to flash memory 18 as a data target. Toggle switch 30 is used to toggle between append mode and overwrite mode. In append mode, data from the data source is appended to data previously stored in the data target. In overwrite mode, data from the data source is written over data previously stored in the data target. Note that in both modes, all the data in the source is written to the target: it is not possible to select only part of the data from the source to write to the target without the intervention of a computer coupled to USB interface 14. The data in the data source is written to the data target until either all the data in the data source is written to the data target or there is no room left in the data target. Toggle switch 32 is used to control the structure of the data that is written to the data target. The written data can be structured, either with the same file structure as in the data source, or as a single file.

LED 22 lights up to indicate that device 10 is coupled to a computer at USB interface 14. LED 24 lights up to indicate that device 10 is coupled to a mass storage device at second interface 16. Button 34 is pressed by the user to initiate data exchange between flash memory 18 and a mass storage device inserted in second interface 16 in accordance with the settings of toggle switches 28, 30 and 32. When button 34 is pressed, LED 26 lights up and remains illuminated until the data exchange is completed. Preferably LED 26 blinks to indicate a failed attempt to exchange data.

When device 10 is plugged into a computer to emulate two auxiliary hard disks, the only features of user interface 20 that are used are LEDs 22, 24 and 26, to indicate positive coupling to the computer at interface 14 and to the mass storage device at interface 16, and to indicate success and failure of the data transfer. The data exchange is initiated by the computer. In this case, the computer can select only a portion of the data from the source to write to the target. Optionally, device 10 is plugged into a computer for the selection of data to be written from the source to the target with the selection being stored in the memory of controller 12; and then device is unplugged from the computer, the mass storage device is inserted in interface 16, and button 34 is pressed to initiate the exchange.

Device 10 is powered by a rechargeable battery 10. Battery 10 is charged via USB interface 14 and controller 12 when device 10 is coupled to a computer at USB interface 14.

Controller 12 preferably is implemented as a programmable microprocessor whose instructions are stored either in flash memory 18 or in a separate non-volatile memory. Alternatively, because controller 12 generally need not be reprogrammed subsequent to manufacture, controller 12 is implemented as a plurality of logic gates. Note that when controller 12 is implemented as a programmable microprocessor, the instructions provided for controller 12 are limited to the instructions needed for the functionality of device 10 as a data storage and exchange device.

While the invention has been described with respect to a limited number of embodiments, it will be appreciated that many variations, modifications and other applications of the invention may be made.

What is claimed is:

1. A data storage and exchange device comprising:
(a) a non-volatile memory;
(b) a first interface, for exchanging data between a computer and said non-volatile memory; and
(c) a second interface, for exchanging data between said computer and a mass storage device;
the data storage and exchange device being operative only to perform said exchanging.

2. The device of claim 1, wherein said non-volatile memory is a flash memory.

3. The device of claim 1, wherein said first interface is a direct contact interface.

4. The device of claim 3, wherein said direct contact interface is a USB interface.

5. The device of claim 3, wherein said direct contact interface is an IEEE 1394 interface.

6. The device of claim 1, wherein said first interface is a wireless interface.

7. The device of claim 6, wherein said wireless interface is a Bluetooth interface.

8. The device of claim 1, further comprising:
(d) a controller for managing said exchanging.

9. The device of claim 8, wherein said controller is operative to perform, on said data, only data processing operations selected from the group consisting of reformatting, compression, decompression, encryption and decryption.

10. The device of claim 8, wherein said interfaces are dissimilar, and wherein said controller is operative to reformat input from one said interface to be compatible with the other said interface.

11. A data storage and exchange device comprising:
(a) a non-volatile memory;
(b) a first interface, for exchanging data between a computer and said non-volatile memory; and
(c) a second interface, for exchanging data between said computer and a mass storage device, and for exchanging data between said non-volatile memory and said mass storage device;
the data storage and exchange device being operative only to perform said exchanging.

12. The device of claim 11, wherein said non-volatile memory is a flash memory.

13. The device of claim 11, wherein said first interface is a direct contact interface.

14. The device of claim 13, wherein said direct contact interface is a USB interface.

15. The device of claim 13, wherein said direct contact interface is an IEEE 1394 interface.

16. The device of claim 11, wherein said first interface is a wireless interface.

17. The device of claim 16, wherein said wireless interface is a Bluetooth interface.

18. The device of claim 11, further comprising:
(d) a controller for managing said exchanging.

19. The device of claim 18, wherein said controller is operative to perform, on said data, only data processing operations selected from the group consisting of reformatting, compression, decompression, encryption and decryption.

20. The device of claim 18, wherein said interfaces are dissimilar, and wherein said controller is operative to reformat input from one said interface to be compatible with the other said interface.

21. The device of claim 11, wherein said exchanging data between said non-volatile memory and said mass storage device includes writing said data from said non-volatile memory to said mass storage device by appending said data from said non-volatile memory to other data previously stored in said mass storage device.

22. The device of claim 21, wherein said data that are written to said mass storage device are structured as a single file.

23. The device of claim 21, wherein said data that are written to said mass storage device are structured as in said non-volatile memory.

24. The device of claim 11, wherein said exchanging data between said non-volatile memory and said mass storage device includes writing said data from said mass storage device to said non-volatile memory by appending said data from said mass storage device to other data previously stored in said non-volatile memory.

25. The device of claim 24, wherein said data that are written to said non-volatile memory are structured as a single file.

26. The device of claim 24, wherein said data that are written to said non-volatile memory are structured as in said mass storage device.

27. The device of claim 11, wherein said exchanging data between said non-volatile memory and said mass storage device includes overwriting data previously stored in said mass storage device with other data from said non-volatile memory.

28. The device of claim 27, wherein said other data are structured as a single file.

29. The device of claim 27, wherein said other data are structured as in said non-volatile memory.

30. The device of claim 11, wherein said exchanging data between said non-volatile memory and said mass storage device includes overwriting data previously stored in said non-volatile memory with other data from said mass storage device.

31. The device of claim 30, wherein said other data are structured as a single file.

32. The device of claim 30, wherein said other data are structured as in said mass storage device.

33. The device of claim 11, further comprising:
(d) a user interface for managing said exchanging data between said non-volatile memory and said mass storage device.
